(19) United States
(12) Patent Application Publication
(10) Pub. No.: US 2024/0313839 A1
(43) Pub. Date: Sep. 19, 2024

(54) CLASSIFICATION OF CSI COMPRESSION QUALITY

(71) Applicant: Telefonaktiebolaget LM Ericsson (publ), Stockholm (SE)

(72) Inventors: Lars LINDBOM, Karlstad (SE); Rakesh RANJAN, Järfälla (SE)

(21) Appl. No.: 18/576,458

(22) PCT Filed: Jul. 7, 2021
(86) PCT No.: PCT/SE2021/050694

§ 371 Date: Jan. 4, 2024

(51) Int. Cl. H04B 7/06; H04B 7/0413; H04L 1/00

(52) U.S. Cl. CPC H04B 7/0626; H04B 7/0413; H04L 1/0033

(57) ABSTRACT

A method, a user equipment, UE, a network node, and a computer program product for classifying channel state information, CSI, compression quality in a wireless communication network are provided. The method is performed in a UE in the wireless communication network. The method includes obtaining CSI associated with one or more radio channels. Further, the method includes compressing the CSI into an encoded format representing a compressed CSI. The method further includes classifying a CSI compression quality related to reconstruction of the one or more radio channels of the compressed CSI using a classifier predicting a resulting performance loss associated with the reconstruction of the one or more radio channels. The classification of the CSI compression quality is based on a level of predicted performance loss.

### TECHNICAL FIELD

The present disclosure relates generally to the field of wireless communication. More particularly, it relates to method, user equipment, UE, network node and computer program products for classification of channel state information, CSI, compression quality, in a wireless communication network.

### BACKGROUND

Multiple antenna techniques have become more prevalent as a way to increase throughput from a base station to a user equipment, UE. Such multiple antenna techniques include single user multiple-input multiple-output, SU-MIMO and multiple user MIMO, MU-MIMO. The use of MIMO technology has taken off from the use of a single transmit antenna and a single receive antenna, and data transmission is performed using multiple transmit antennas and multiple receive antennas. This is a technique for improving transmission and reception efficiency. A receiving side receives data through a single antenna path when using a single antenna, but receives data through multiple paths when using multiple antennas. A transmitting side transmits data through multiple antennas, which enables beamforming of the transmissions. Therefore, it is possible to improve the transmission speed and transmission amount of data, and to increase the coverage.

Single-cell MIMO operation includes a SU-MIMO scheme in which one UE receives a downlink signal in one cell, and two or more UEs can be distinguished from a MU-MIMO system that receives a downlink signal in one cell. For MU-MIMO operations, a multi-antenna base station with multiple antenna ports spatially transmit information to several UEs, in which a first sequence S⁽¹⁾ is intended for a first UE and a second sequence S⁽²⁾ is intended for a second UE and so on. Before modulation and transmission, precoding is applied to each of the sequence to spatially separate the transmissions, i.e., to mitigate multiplexing interference.

Channel estimation refers to the process of recovering a received signal by compensating for signal distortion caused by fading. For channel estimation, a reference signal that is known by both the transmitter and the receiver is required. Further, the reference signal may be Reference Signal, RS, and may be referred to as a pilot signal depending on an applied standard.

In OFDM based wireless communication systems, such as NR and LTE, data is transmitted over multiple subcarriers where a MIMO channel, observed on a subcarrier within one OFDM symbol, can be represented as a complex-valued channel (gain) matrix of dimension N_{RX}×N_{TX}, with N_{RX} and N_{TX} denoting the number of receive antenna and transmit antenna ports, respectively. The MIMO channel is estimated on OFDM resources carrying reference signals and in case reference signals are mapped on N_{sc} subcarriers within an OFDM symbol, there will be N_{sc}×N_{RX}×N_{TX} complex-valued channel coefficients to estimate. In the following, the notation H is used for representing a MIMO channel with N_{SC} channel (gain) matrices of dimension N_{RX}×N_{TX}. The format of H, in terms of array dimensions, for representing the MIMO channel may depend on the use case.

To construct precoders for efficient MU-MIMO transmissions, the base station needs to acquire knowledge of the MIMO channels, H, for each UE. In deployments where channel reciprocity holds, channel knowledge can be acquired from sounding reference signals, SRS, that are transmitted periodically, or on demand, by active UEs. Based on these SRS, the base station estimates H for each UE. However, when channel reciprocity does not hold, active UEs need to feedback channel state information, CSI to the base station. In new radio systems (as well as in LTE), the channel estimation for deriving CSI is performed by having the base station to periodically transmit channel state information reference signals, CSI-RS from which a UE can estimate its channel. The UE then reports CSI from which the base station can determine suitable precoders for MU-MIMO.

The CSI feedback mechanism primarily targeting MU-MIMO operations in NR is referred to as CSI type II, in which the UE reports CSI feedback with high CSI resolution. The CSI type II represents a MIMO channel feedback mechanism where a UE reports precoder hypothesis that trades CSI resolution towards uplink transmission overhead.

The CSI type II is a suboptimal precoding approach for MU-MIMO transmissions with respect to knowing the UE estimated MIMO channels at the base station, but explicit signalling of the full MIMO channel is impractical considering resulting uplink capacity. However, signaling of a highly compressed MIMO channel is feasible and recently neural network based autoencoders have achieved significant performance in terms of providing good compression-decompression performance with realistic overhead.

An autoencoder, AE, is a type of artificial neural network, NN, which can be used for compression and decompression of radio channels in an unsupervised manner, in which the AE works with only input data and no output labels are needed. These networks aim to reconstruct the input channels at an output layer.

An implementation of the AE can be based on different types of NN architectures, possibly including one or more fully connected layers namely dense layers, where the NN is divided into an encoder i.e., AE-encoder and a decoder i.e., AE-decoder. The output of the AE-encoder, sometimes referred to as the bottleneck layer, represents the code values that are to be signalled. The AE is trained for a given input feature, and code size, to provide small reconstructions errors. The optimization may refer to minimization of the mean squared error, MSE, of the reconstruction error, i.e. the difference between input and output of the AE.

FIG. 1A exemplifies an elementary AE using fully connected layers, where X is an input feature, Z is the code which is an output of the AE-encoder and \hat{X} is an output of the AE-decoder which is the reconstruction of the input feature X. The size of the code Z of the AEs is typically significantly smaller than the size of the input data X. The AE-encoder reduces spatial dimensionality of the input feature with increasing depth of the neural network. The AE-decoder basically performs an inverse operation i.e., the AE-decoder gradually turns the compressed code Z to increase to an original size of the input feature. At the output layer, the AE-decoder reconstructs the original input feature with some loss, resulting in a reconstruction error, \tilde{X}=X−\hat{X}.

The AE can be applied to MIMO channels as illustrated in FIG. 1B, where an input to the AE-encoder represents a MIMO channel estimated over several subcarriers, SC, and antenna ports. For compressing CSI, the encoder is implemented in the UE, whereas the decoder is implemented in the base station. However, the decoder may also be located in other nodes associated with a radio access network, RAN.

Although the AEs can be applied to the MIMO channels, the AEs represent class of lossy encoders for compressing the CSI and there exist reconstruction errors of the CSI. The magnitude of these reconstruction errors may depend on how the neural network can model channel characteristics as well as the size of the code. For obtaining realistic CSI, in uplink, the compression ratio i.e., a size of the input data to the code must be high which leads to lossy reconstructions of the original CSI.

Further, some MIMO channels are difficult to compress and decompress accurately. For example, high frequency selectivity MIMO channels are more difficult to compress accurately than MIMO channels that are less frequency selectivity. The amount of channel frequency selectivity typically varies for moving UEs because of multipath radio propagation changes. When using AEs or any other lossy compression schemes, the base station that performs channel decompression may not determine whether the decompression results in an accurate reconstruction of the uncompressed channel or not. When the reconstructed MIMO channel is not optimal, it may have an impact on determining the precoders for downlink transmissions that may significantly affect the transmission and reception efficiency.

Consequently, there is a need for an improved method and arrangement for predicting channel compression and decompression quality or accuracy of channel compression and decompression that alleviates at least some of the above cited problems.

### SUMMARY

It is therefore an object of the present disclosure to provide a method, a user equipment, a network node, and a computer program product for classifying channel state information, CSI, compression quality that seeks to mitigate, alleviate, or eliminate all or at least some of the above-discussed drawbacks of presently known solutions.

This and other objects are achieved by means of a method, a computer program product, and a device as defined in the appended claims. The term exemplary is in the present context to be understood as serving as an instance, example or illustration.

According to a first aspect of the present disclosure, a method for classifying channel state information, CSI, compression quality is provided. The method is performed by a user equipment, UE, in a wireless communication network. The method comprises obtaining CSI associated with one or more radio channels. Further, the method comprises compressing the CSI into an encoded format representing a compressed CSI. The method further comprises classifying a CSI compression quality related to reconstruction of one or more radio channels of the compressed CSI using a classifier predicting a resulting performance loss associated with the reconstruction of the one or more radio channels. The classification of the CSI compression quality is based on a level of predicted performance loss.

In some embodiments, the method further comprising transmitting one or more of: the CSI compression quality classification and the encoded format representing the compressed CSI to a network node in the wireless communication network.

In some embodiments, the method comprises determining whether the CSI compression quality classification triggers a secondary CSI report. Further, the method comprises transmitting one or more of: the CSI compression quality classification and the secondary CSI report when it is determined that CSI compression quality classification triggers a secondary CSI report.

In some embodiments, the secondary CSI report is configured by the network node.

In some embodiments, wherein a type of the secondary CSI report is configured by the network node.

In some embodiments, the secondary CSI report is an NR CSI type I report.

In some embodiments, the CSI compression quality is classified using a neural network based classifier.

In some embodiments, the neural network based classifier is configured by the network node.

In some embodiments, the classifier is trained by generating an encoded format representing the compressed CSI for one or more radio channels. The method further comprises determining a performance loss associated with the reconstruction of the CSI from the compressed CSI. Further, the method comprises defining two or more classification labels, wherein each of the classification labels being associated with the determined performance loss. The method comprises extracting input data to the classifier from data associated with the compression of the CSI. Further, the method comprises training the classifier using extracted input data and the generated two or more classification labels for classifying the CSI compression quality.

In some embodiments, the CSI compression is performed by using a neural network, wherein the extracted input data to the classifier corresponds to one or more layers of a CSI compression based neural network.

In some embodiments, a neural network is used to obtain a reconstructed CSI from the encoded format representing the compressed CSI of one or more radio channels.

In some embodiments, the neural network represents a decoder of an autoencoder.

According to a second aspect of the present disclosure, a method for classifying channel state information, CSI, compression quality, the method being performed by a network node in a wireless communication network is provided. The method is performed by a network node, for example, a base station in the wireless communication network. The method comprises receiving an encoded format representing a compressed CSI from a user equipment, UE. The method comprises classifying a CSI compression quality related to reconstruction of one or more radio channels of the compressed CSI using a classifier predicting a resulting performance loss associated with the reconstruction of the one or more radio channels, wherein the classification of the CSI compression quality is based on a level of predicted performance loss.

In some embodiments, the CSI compression quality is classified using a neural network based classifier.

In some embodiments, the method further comprising deciding on how to use a CSI feedback for scheduling the UE using the classified CSI compression quality.

In some embodiments, the step of deciding on how to use a CSI feedback for scheduling the UE using the classified CSI compression quality comprises deciding whether to schedule a multi-user MIMO or a single-user MIMO transmission for the UE using the classified CSI compression quality.

In some embodiments, the classifier is trained by generating an encoded format representing the compressed CSI for one or more radio channels. The method comprises determining a performance loss associated with the reconstruction of the CSI from the compressed CSI. The method further comprises defining two or more classification labels, wherein each of the classification labels being associated with the level of determined performance loss. The method further comprises training the classifier using the extracted input data and the generated two or more classification labels for classifying the CSI compression quality.

In some embodiments, the reconstruction of CSI or decompression of CSI is performed by using a neural network, wherein the extracted input data to the classifier corresponds to one or more layers of the neural network used to reconstruct or decompress the compressed CSI of one or more radio channels.

In some embodiments, a neural network is used to obtain the reconstructed CSI from the encoded format representing the compressed CSI of one or more radio channels.

In some embodiments, the neural network represents a decoder of an autoencoder.

According to a third aspect of the present disclosure, a user equipment, UE, for classifying channel state information, CSI, compression quality, in a wireless communication network is provided. The UE being adapted for obtaining CSI associated with one or more radio channels. The UE being adapted for compressing the CSI into an encoded format representing a compressed CSI. Further, the UE being adapted for classifying a CSI compression quality related to reconstruction of the one or more radio channels of the compressed CSI using a classifier predicting a resulting performance loss associated with the reconstruction of the one or more radio channels wherein the classification of the CSI compression quality is based on a level of predicted performance loss.

According to a fourth aspect of the present disclosure, a network node for classifying channel state information, CSI, in a wireless communication network is provided. The network node being adapted for receiving an encoded format representing a compressed CSI from a user equipment, UE. The network node being adapted for classifying a CSI compression quality related to reconstruction of one or more radio channels of the compressed CSI using a classifier predicting a performance loss associated with the reconstruction of the one or more radio channels, wherein the classification of the CSI compression quality is based on a level of predicted performance loss.

According to a fifth aspect of the present disclosure, there is provided a computer program product comprising a non-transitory computer readable medium, having thereon a computer program comprising program instructions. The computer program is loadable into a data processing unit and configured to cause execution of the method according to any of the first and second aspects when the computer program is run by the data processing unit.

An advantage of some embodiments is that alternative and/or improved approaches are provided for classification of channel state information, CSI, quality by using autoencoders with radio channels as input.

An advantage of some embodiments is that a base station may use the predicted CSI quality for scheduling decisions such that UEs with predicted low CSI compression quality are candidates for single user MIMO, SU-MIMO, transmissions.

An advantage of some embodiments is that, the base station may use the output of the classifier i.e., the CSI compression quality to induce different levels of robustness for precoder design.

An advantage of some embodiments is that, the UE may not need to implement a complex decoder to determine reconstruction errors from which the CSI compression quality can be predicted.

An advantage of some embodiments is that, the classifier may be designed to predict the impact of erroneous channel reconstructions that use reconstructed MIMO channels.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the example embodiments.

FIG. 1A is an example illustration of an autoencoder;

FIG. 1B discloses an example illustration of autoencoder for channel state information, CSI compression;

FIG. 2 discloses an example wireless communication network according to some embodiments.

FIG. 3 is a flowchart illustrating example method steps performed by a user equipment, UE, for classifying channel state information, CSI, compression quality according to some embodiments;

FIG. 4 is a flow chart illustrating example method steps performed by a base station for classifying CSI compression quality according to some embodiments;

FIG. 5 is a signal flow diagram for obtaining a channel reconstruction error according to some embodiments;

FIG. 6 discloses training of a classifier for supervised learning according to some embodiments;

FIG. 7 discloses various examples of implementing classifiers for predicting CSI compression quality according to some embodiments;

FIG. 8 discloses another example of implementing a classifier for transfer learning, according to some embodiments;

FIG. 9 is an example schematic diagram showing functional modules of the UE according to some embodiments;

FIG. 10 is an example schematic diagram showing functional modules of the network node according to some embodiments;

FIG. 11 is a graph showing predicted classification of CSI compression quality according to some embodiments;

FIG. 12 is a graph showing receiver operating characteristic, ROC, of CSI compression quality according to some embodiments;

FIG. 13 discloses an example computing environment according to some embodiments.

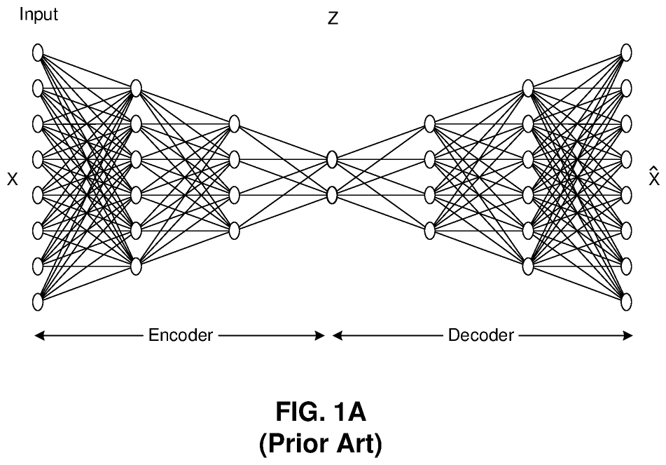

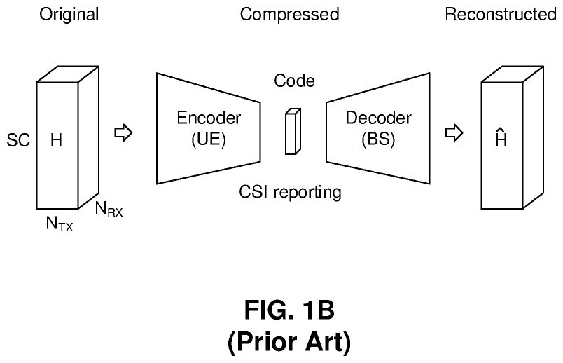

### DETAILED DESCRIPTION

Aspects of the present disclosure will be described more fully hereinafter with reference to the accompanying drawings. The apparatus and method disclosed herein can, however, be realized in many different forms and should not be construed as being limited to the aspects set forth herein. Like numbers in the drawings refer to like elements throughout.

The terminology used herein is for the purpose of describing particular aspects of the disclosure only, and is not intended to limit the invention. It should be emphasized that the term “comprises/comprising” when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

Embodiments of the present disclosure will be described and exemplified more fully hereinafter with reference to the accompanying drawings. The solutions disclosed herein can, however, be realized in many different forms and should not be construed as being limited to the embodiments set forth herein.

It will be appreciated that when the present disclosure is described in terms of a method, it may also be embodied in one or more processors and one or more memories coupled to the one or more processors, wherein the one or more memories store one or more programs that perform the steps, services and functions disclosed herein when executed by the one or more processors.

In the present disclosure, user equipment(s), UE(s), also known as mobile terminals, and/or wireless terminals are enabled to communicate wirelessly with a network node in a wireless communication network.

Typically, a network node may serve or cover one or several cells of the wireless communication network. That is, the network node provides radio coverage in the cell(s) and communicates over an air interface with the UE(s) operating on radio frequencies within its range. The network node may also be referred to as “eNB”, “eNodeB”, “NodeB” or “gNB”, depending on the technology and terminology used. In the present disclosure, the network node device may also be referred to as a base station, BS.

In the present disclosure, it is assumed that connection establishment has already been completed between the UE(s) and the network node.

In the present disclosure, it is considered that a resulting reconstruction error associated with the reconstruction of one or more radio channels may cause a performance loss for which a CSI compression quality is classified based on a level of predicted performance loss.

In the following description of exemplary embodiments, the same reference numerals denote the same or similar components.

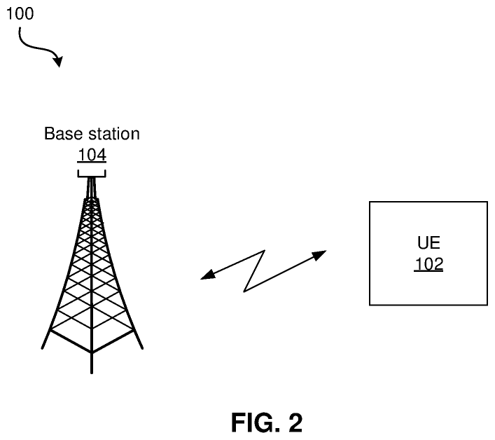

FIG. 2 discloses an example wireless communication network 100. As depicted in FIG. 2, the wireless communication network 100 includes a user equipment, UE 102 and a base station 104.

The base station 104 may be for example a new radio, NR, base station i.e., a gNB or an evolved node base station i.e., eNB, or the like. The UE 102 communicates with the base station 104 serving the UE 102. The communication from the base station 104 to the UE 102 is referred to as downlink, DL, communication, whereas communication from the UE to the base station is referred to as uplink, UL, communication. Thus, the UE 102 involves in bidirectional radio communication with the base station 104.

The UE 102 receives communications from the base station 104 over a forward link multiple input multiple output, MIMO channel. In FIG. 2, a transmit antenna located in the base station 104 is utilized to transmit signals to one or more UEs (not shown in FIG. 2). Appropriate precoding is applied to the plurality of transmit antennas to simultaneously transmit to a plurality of UEs. In general, the number of information streams that one UE can receive is determined by the number of reception antennas held by the terminal, channel conditions, and receiver performance.

In order to effectively implement the MIMO system, the UE 102 must accurately measure channel conditions and the magnitude of interference, and transmit effective channel state information to the base station 104. The base station 104 receiving the channel state information uses this to transmit to which terminal in connection with the transmission of the downlink, at which data transmission rate to transmit, what precoding to apply, etc. In the case of the MIMO system, since the number of transmitting antennas is large, when applying the conventional transmission and reception method of channel state information, it is necessary to transmit much of control information in the uplink which causes overhead problems.

However, signaling of a highly compressed MIMO channel is feasible and recently neural network based compression-decompression schemes as autoencoders, AEs, have achieved significant performance in terms of providing good compression-decompression performance with realistic overhead.

An implementation of the autoencoder can be based on different types of neural network architectures, possibly including one or more fully connected layers, where the neural network is divided into an encoder and a decoder.

Although the AEs can be applied to the MIMO channels, the AEs are class of lossy encoders for compressing the CSI and there exist reconstruction errors of the CSI. The magnitude of these reconstruction errors may depend on how the neural network can model channel characteristics as well as the size of the code. For obtaining realistic CSI, in uplink, the compression ratio i.e., the size of the input data to the code must be high which leads to lossy reconstructions of the original CSI.

Therefore, according to some embodiments of the present disclosure, the UE 102 implements a method for efficiently classifying channel state information, CSI compression quality using a neural network based classifier as described herein. Alternatively, the base station 104 may implement the method for efficient classification of CSI compression quality using the neural network based classifier.

According to some embodiments of the present disclosure, the UE 102 obtains CSI associated with one or more radio channels. When the UE 102 obtains the CSI associated with the one or more radio channels, the UE performs compression of the CSI, where the CSI is compressed into an encoded format representing a compressed CSI. The UE 102 may perform compression of the CSI using autoencoder. Further, the UE 102 classifies a CSI compression quality related to reconstruction of the one or more radio channels of the compressed CSI. The UE classifies the CSI compression quality using a classifier, where the classifier predicts a resulting channel reconstruction error or performance loss associated with the reconstruction of one or more radio channels. The classification of the CSI compression quality is based on a level of the channel reconstruction error or performance loss associated with the reconstruction of one or more radio channels.

Further, the UE 102 transmits CSI compression quality classification and the encoded format representing the compressed CSI to the base station 104 in the wireless communication network 100.

In some embodiments, the UE 102 determines whether the CSI compression quality classification triggers a secondary CSI report. Further, the UE 102 transmits the CSI compression quality classification and the secondary CSI report when the UE 102 determines that the CSI compression quality classification triggers a secondary CSI report.

In an embodiment, the secondary CSI report and a type of the secondary CSI report may be configured by the base station 104. For example, the secondary CSI report is an NR CSI type I report.

It should be noted that the UE 102 implements a trained neural network based classifier for classifying the CSI compression quality and the trained neural network based classifier may be configured by the base station 104. The neural network based classifier may be trained using input data associated with the compression of the CSI and the trained neural network based classifier may be used to classify the CSI compression quality.

The classifier may be implemented at the UE 102 or the classifier may be implemented at the base station 104 for classifying the CSI compression quality.

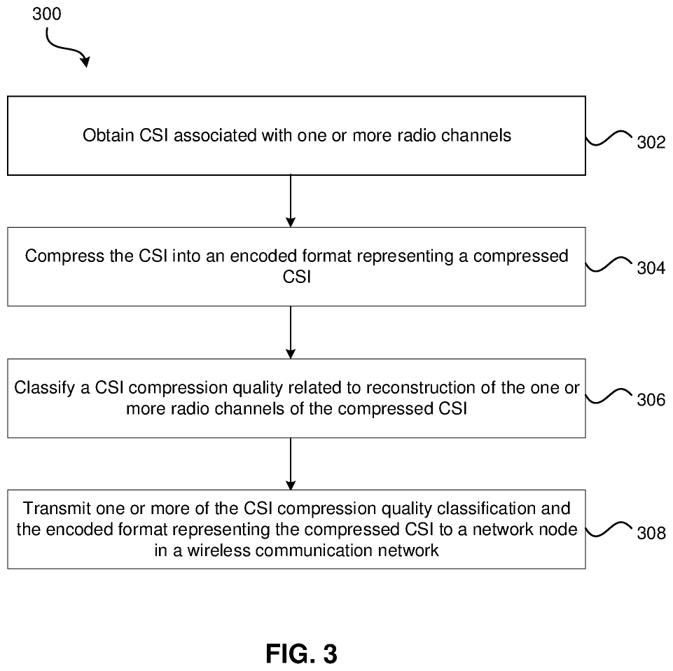

FIG. 3 is a flowchart illustrating an example method 300 for classifying CSI compression quality. As stated above, the UE performs the method 300 for classifying the CSI compression quality. The UE implements a trained neural network based classifier which is used for CSI compression quality inference in terms of predicting performance loss associated with the reconstruction of one or more radio channels used in the compression. The classification of the CSI compression quality is based on a level of predicted performance loss.

In an example, the neural network based classifier may be a multi-level classifier where a resulting channel reconstruction error causing the performance loss may be classified into multiple levels depending on the resulting channel reconstruction error.

In another example, the neural network based classifier may be a binary classifier where the resulting channel reconstruction error may be classified into two levels or labels (e.g., either 0 or 1) depending on the resulting channel reconstruction error.

In some examples, the resulting performance loss may be compared with a threshold value. In case, the resulting performance loss is higher than the threshold value, then the CSI compression quality is classified with label “1” which indicates that the performance loss has a larger impact on application performance. When the resulting performance loss is lower than the threshold value, then the CSI compression quality is classified with label “0” which indicates that the performance loss has no or minor impact on the application performance. Thus, the neural network based classifier is used for classification of the CSI compression quality.

In a case where classifying of the CSI compression quality is conducted by a UE that is capable of determining or estimating the resulting performance loss, such UE may be configured with one or more threshold values that corresponds to a performance loss, or a range of performance losses, observed by the network. In this case, the UE has implemented a (reference) decoder that is used to reconstruct the compressed CSI. The threshold value for comparing the resulting performance loss for classification of the CSI compression quality may in such cases be indicated to the UE by the base station.

At step 302, the method 300 comprises obtaining CSI associated with one or more radio channels. For example, the one or more radio channels represent one or more of: MIMO channels, SIMO channels and MISO channels and the like.

At step 304, the method 300 comprises compressing the CSI into an encoded format representing a compressed CSI. For example, the CSI is compressed using the encoder of an autoencoder. In another example, a function, or an algorithm, for performing CSI compression may be utilized for compressing the CSI in order to minimize a compression-decompression error. The function may represent any type of lossy data compression method but an autoencoder is used with encoder and decoder being trained to minimize a certain loss function. This training may include minimizing the mean squared error of the channel reconstruction error, \tilde{H} associated with reconstruction of one or more radio channels which is more generally expressed of an error, \tilde{W}, caused by taking a “lossy” channel reconstruction \tilde{H} as input to an application function, ƒ(\tilde{H}), that takes channel estimates or predictions as inputs.

In some embodiments, for each input feature of H, a corresponding code Z which is an encoded format representing the compressed CSI is obtained and an input feature reconstruction \tilde{H}, from which the corresponding \tilde{H}, and \tilde{W}, can be derived. Hence, \tilde{H} and \tilde{W} can be associated with either H or Z or Ĥ, or possibly to any neural network layer within the autoencoder. When both the encoder and the decoder are implemented by the UE, the reconstruction error \tilde{H} may be calculated.

At step 306, the method 300 comprises classifying the CSI compression quality related to reconstruction of one or more radio channels of the compressed CSI using a classifier to predict a resulting channel reconstruction error or performance loss associated with the reconstruction of one or more radio channels used in the compression.

In some embodiments, a trained neural network based classifier is used for predicting a resulting channel reconstruction error or performance loss associated with the reconstruction of one or more radio channels used in the compression. In an example, the trained neural network based classifier is configured by the base station.

The neural network based classifier may be trained using supervised learning with the encoded format representing a compressed CSI as input to predict a class or label that corresponds to a certain channel reconstruction error, causing performance loss, which is associated with the reconstruction of the one or more radio channels for classifying CSI compression quality.

The neural network-based classifier for classifying CSI compression quality obtains the output of an encoder, which is an encoded format representing a compressed CSI, as an input to predict a class in the classification of CSI compression quality. Further, the neural network based classifier predicts a class that relates to a resulting performance loss associated with the reconstruction of one or more radio channels used in the compression.

In an example, a class in the classification of the CSI compression quality is based on a level of performance loss associated with the reconstruction of one or more radio channels used in the compression.

In an example, a class related to predicting a performance loss associated with the reconstruction of one or more radio channels used in the compression may refer to a case where reconstructed CSI is used to perform beamforming or precoding.

In another example, the neural network based classifier may be a multi-level classifier where the performance loss may be classified into multiple levels depending on the resulting performance loss.

In another example, the neural network based classifier may be a binary classifier where the performance loss, may be classified into two levels or labels (e.g., either label 0 or label 1) depending on the resulting performance loss. When the resulting performance loss is lower than the threshold value, then the CSI compression quality is classified with label “0” which indicates that the performance loss has no or minor impact on the application performance.

At step 308, the method 300 comprises transmitting one or more of: the CSI compression quality classification and the encoded format representing the compressed CSI to the base station. The UE transmits the predicted CSI compression quality classification and the encoded format representing the compressed CSI, i.e., the code to the base station.

In an embodiment, the UE 102 determines whether the CSI compression quality classification triggers a secondary CSI report. For example, when the magnitude of the resulting performance loss is higher than the threshold value, then the CSI compression quality is classified with label “1” which indicates for a binary classifier that the performance loss has a larger impact on application performance. Upon determining that the CSI compression quality classification triggers a secondary CSI report, the UE transmits the CSI compression quality classification and the secondary CSI report to the base station.

In an example, the secondary CSI report and a type of the secondary CSI report is configured by the base station. In another example, the secondary CSI report is a NR CSI type 1 report configured by the base station.

The secondary CSI report which is a NR CSI type 1 report may be used by the base station for deciding whether to schedule a single user MIMO, SU-MIMO for the UE.

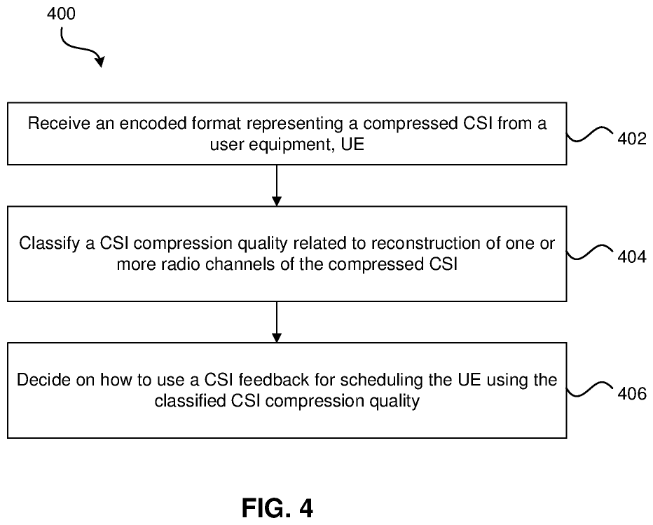

FIG. 4 is a flowchart illustrating an example method 400 performed by a base station for classifying CSI compression quality for classifying CSI compression quality. The base station may implement a decompression scheme that may refer to a decoder of an autoencoder to reconstruct the one or more radio channels from the compressed CSI, which is transmitted to the base station by the UE.

As explained above, the base station may also implement a trained neural network based classifier which is used for predicting a resulting performance loss associated with the reconstruction of one or more radio channels used in the compression. The classification of the CSI compression quality may be based on a level of predicted performance loss.

In an example, the neural network based classifier may be binary classifier or a multi-level classifier for predicting a resulting performance loss associated with the reconstruction of one or more radio channels used in the compression.

It should be noted that when labelling for CSI compression quality classification, the resulting performance loss may be compared with a threshold value. In case, the resulting performance loss is higher than the threshold value, then the CSI compression quality is classified with label “1” which for a binary classifier indicates that the performance loss has a larger impact on application performance. When the output of the binary classifier indicates “0”, implying that the resulting performance loss is lower than the threshold value, then the CSI compression quality is classified as that the performance loss has no or minor impact on the application performance.

At step 402, the method 400 comprises receiving an encoded format representing a compressed CSI from the UE. The encoded format represents a code, Z, generated by compressing the CSI using the encoder of the autoencoder. The base station may receive the generated code Z, which is the encoded format representing the compressed CSI from the UE. The decoder of the autoencoder may obtain the encoded format representing the compressed CSI.

At step 404, the method 400 comprises classifying a CSI compression quality related to reconstruction of one or more radio channels of the compressed CSI using a classifier predicting performance loss associated with the reconstruction of the one or more radio channels used in the compression.

In an embodiment, a trained neural network based classifier is used for predicting the performance loss associated with the reconstruction of one or more radio channels used in the compression.

In an example, the classification of the CSI compression quality is based on a level of performance loss associated with the reconstruction of one or more radio channels used in the compression.

In another example, the neural network based classifier may be a multi-class classifier where different levels of performance loss may be classified as multiple classes.

In another example, the neural network based classifier may be a binary classifier where the performance loss may be classified into two levels or labels (i.e., either label 0 or label 1) depending on the performance loss.

In some examples, the resulting performance loss may be compared with a threshold value. In case, the resulting performance loss is higher than the threshold value, then the CSI compression quality is classified with label “1” which indicates that the performance loss has a larger impact on application performance. When the resulting performance loss is lower than the threshold value, then the CSI compression quality is classified with label “0” which indicates that the performance loss has no or minor impact on the application performance.

At step 406, the method 400 comprises deciding on how to use a CSI feedback for scheduling the UE using the classified CSI compression quality.

In an embodiment, the base station decides whether to use a SU-MIMO or a MU-MIMO using the classified CSI compression quality.

In an embodiment, the base station determines whether the CSI compression quality classification triggers a request of a secondary CSI report, which may be an NR CSI type I report. For example, when the resulting performance loss is higher than the threshold value, then the CSI compression quality is classified with label “1” which indicates that the performance loss has a larger impact on application performance. When the performance loss has a larger impact on application performance, the base station determines that the CSI compression quality classification triggers request of a secondary CSI report. Upon determining that the CSI compression quality classification triggers a secondary CSI report, the base station schedules a SU-MIMO to the UE.

In another embodiment, when the resulting performance loss is less than the configured threshold value, then the CSI compression quality is classified with label “0” which indicates that the performance loss has a no or minor impact on application performance. When the performance loss has a no or minor impact on application performance, the base station may decide to schedule a MU-MIMO transmission for the UE. Thus, the base station may decide to schedule a MU-MIMO or a SU-MIMO transmission for the UE using the classified CSI compression quality.

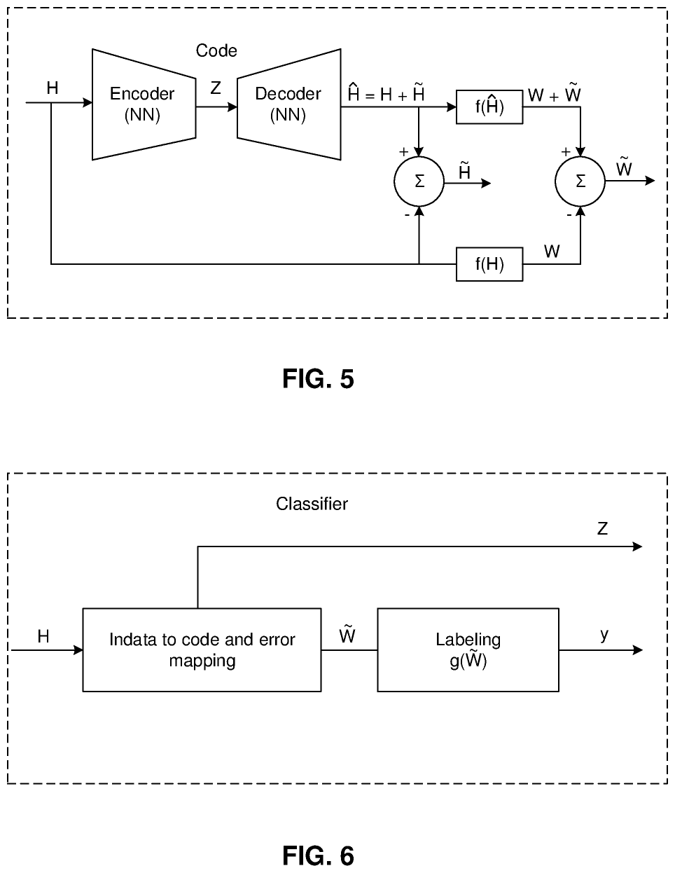

FIG. 5 is a signal flow diagram for obtaining performance loss according to some embodiments.

For example, a function, or an algorithm, for performing CSI compression may be utilized for compressing the CSI in order to minimize a compression-decompression error. The function may represent any type of lossy data compression method but an autoencoder is used with encoder and decoder being trained to minimize a certain loss function. This training may include minimizing the mean squared error of the performance loss, \tilde{H} associated with reconstruction of the one or more radio channels which is more generally expressed of an error, \tilde{W}, caused by taking a “lossy” channel reconstruction Ĥ as input to an application function, ƒ(Ĥ), that takes channel estimates or predictions as inputs.

In some embodiments, for each input feature of H, as shown in FIG. 5, a corresponding code Z which is an encoded format representing the compressed CSI is obtained and an input feature reconstruction Ĥ, from which the corresponding \tilde{H}, and \tilde{W}, can be derived. Hence, \tilde{H} and \tilde{W} can be associated with either H or Z or Ĥ, or possibly to any neural network layer within the autoencoder.

When both the encoder and the decoder are implemented by the UE, the performance loss \tilde{H} can be calculated directly whereas calculation of \tilde{W} requires the application function to be known by the UE. At the base station, only the decoder part of the autoencoder is implemented and the performance loss is predicted from the code Z, signalled by the UE to the base station.

In some embodiments, for generating training data for training the classifier, the labelling may require the input to the AE and the output of the AE. However, the input to the AE-encoder is not available to the base station, therefore, the compressed CSI is provided to the base station. For the UE, the input to the AE is available whereas the output of the AE-decoder is not available, unless the UE has implemented a reference decoder for decompressing the compressed CSI associated with the one or more radio channels.

Thus, uncompressed i.e., original CSI needs to be available to determine a reconstruction error at the base station, from which a performance loss may be assessed.

Training of a classifier for classifying CSI compression quality may be performed by a network node, or any training node entity, that has access to corresponding training and validation data. After the training, one or more trained classifiers may be stored for being accessible by the network node, or any suitable device, which may be used for performing inference by using a trained classifier for classifying CSI compression quality.

Data collection for generating training and validation data may be based on collection of radio channel data from real measurements or/and from synthetic radio channel data obtained via link simulations. The collection of radio channel data from measurements may refer to collecting the data during a mobile drive test or it may refer to collecting the data in an operating network. Further, the data collection may refer to base station estimation of the one or more radio channels from reference signals transmitted by the UEs.

An assessment of the performance loss may be conducted via simulations where the loss can be quantified by comparing performances of using reconstructed CSI with corresponding uncompressed, i.e., original CSI. The performance loss may refer to a reduced effective SINR seen by a UE when receiving transmissions based on a reconstructed CSI. In MU-MIMO transmissions, the SINR reduction may refer to increased cross-scheduling interference.

In an embodiment, a neural network-based classifier for classifying CSI compression quality obtains the output of an encoder, i.e., the code Z which is an encoded format representing, as an input feature to predict a quality class.

The neural network based classifier may be trained for classifying a CSI compression quality related to reconstruction of the one or more radio channels of the compressed CSI. The training of the neural network based classifier comprises generating an encoded format representing the compressed CSI for the one or more radio channels. The encoded format representing the compressed CSI for the one or more radio channels is denoted as ‘Z’. Further, performance loss which is denoted as \tilde{W}, associated with the reconstruction of the CSI from the compressed CSI is determined. For each of the input feature of H, a code ‘Z’ is generated and the performance loss which is denoted as \tilde{W} is determined. Thus, a set of code and performance loss pairs denoted as (Z, \tilde{W}) are generated by running autoencoder that obtains the one or more radio channels as input data as shown in FIG. 5.

In an embodiment, the performance loss is determined using reconstructed CSI by obtaining CSI associated with the one or more radio channels and comparing a CSI associated with the one or more channels with the corresponding reconstructed CSI.

For example, comparing the CSI associated with the one or more radio channels with the corresponding reconstructed CSI includes determining a norm of a performance loss. The determined norm of the performance loss may be used to classify a CSI compression quality when using the reconstructed CSI.

Further, the training of the neural network based classifier comprises defining two or more classification labels, where each of the classification labels being associated with the determined performance loss. For example, a set of labels are generated by introducing a labelling mechanism such that a function, g(\tilde{W}), maps the error \tilde{W} to a certain classification label. The classification labels “y” may be defined as “0” and “1” in case the neural network based classifier is a binary classifier. There may be multiple classification labels that may be defined in case the neural network based classifier is a multi-level classifier.

Furthermore, the training of neural network based classifier includes extracting input data to the classifier from data associated with the compression of the CSI. The input data to the classifier is the data associated with the compression of the CSI. The classifier is trained using the extracted input data and the two or more classification labels for classifying the CSI compression quality. Thus, the neural network based classifier is trained using the training data (Z, y) as shown in FIG. 6.

When the classifier is trained using the training data, the classifier can use the code Z as input to predict the CSI compression quality class of unclassified radio channels.

However, the output of any of the neural network layers of an autoencoder may be used as an input feature to the classifier to predict the CSI compression quality class of unclassified radio channels. Let Z⁽ⁱ⁾ denote the output of the i^{th} layer of an N-layer autoencoder, in which Z⁽⁰⁾ equals H, Z^{(N)} equals Ĥ and Z^{(L)} equals the code Z. The classifier for classifying CSI compression quality obtains the output Z⁽ⁱ⁾ from the i^{th} layer of an N-layer autoencoder as an input feature to predict the CSI compression quality class. In the supervised learning of a neural network based classifier, data set of (Z⁽ⁱ⁾, y) is used for the training.

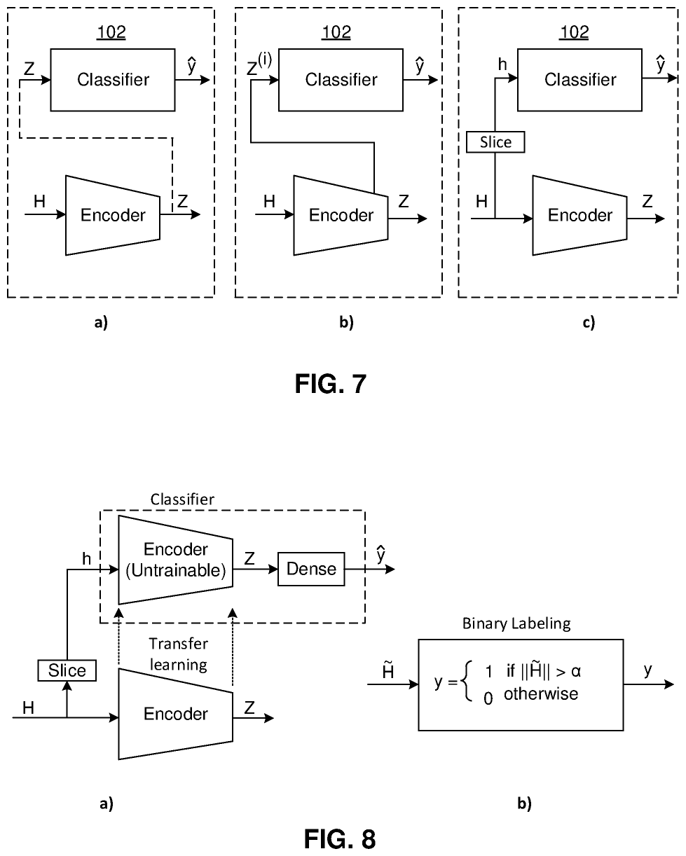

FIG. 7 discloses various examples of implementing classifiers for predicting CSI compression quality according to some embodiments. As described in FIGS. 3 and 4, the classifier for classifying CSI compression quality may be implemented at the UE or at the base station.

The implementation examples shown in FIG. 7(b) and FIG. 7(c) use input data to the classifier that are not available at the base station and can thus only be considered in a UE implementation of the classifier. In the implementation example shown in FIG. 7(a), the classifier uses the code, Z, as input and since the code is signalled to the base station the classifier may, as an option, be implemented at the base station. Hence, the classifier as shown in FIG. 7(a) may either be implemented at the base station or at the UE.

In case, when the classifier is implemented at the base station, the input to the classifier may refer to the code Z (Z^{(L)}) or/and any of the decompressing neural network layer outputs that associates with the AE-decoder, i.e. Z⁽ⁱ⁾, i>L. If the UE with AE-encoder has implemented the classifier, the input to the classifier may refer to any of the compressing neural network layers that relates to the encoder, i.e. Z⁽ⁱ⁾, i≤L.

As the code Z represents a highly compressed version of the channel H and that the dimensions of Z⁽ⁱ⁾, i≠L, are expected to be significantly larger than the bottleneck layer (L) of the autoencoder, using the code Z (Z^{(L)}) as input to the classifier may have a complexity advantage when implementing a neural network based classifier.

When encoding (or compressing) a radio channel, the compression ratio gradually increases by successively downsampling the feature maps from encoder input to the code. This means that some channel information may be lost after downsampling. In case a classifier for classifying CSI compression quality is implemented at the UE, the input to the classifier may refer to uncompressed channel data, which may provide some classification performance advantages.

In an embodiment, where the UE implements the classifier for classifying the CSI compression quality, the classifier uses the output of the AE-encoder as input.

In another embodiment, where the UE implements the classifier for classifying the CSI compression quality, the classifier takes the output from one or more hidden encoder layer outputs as input.

In another embodiment, where the UE implements the classifier for classifying the CSI compression quality, the classifier uses the obtained radio channel as input, wherein the obtained radio channel is part of obtaining CSI associated with the one or more radio channels.

In another embodiment, where the UE implements the classifier for classifying the CSI compression quality, a transformed version of the obtained CSI associated with the one or more radio channels is used as input to the classifier. One example of a transformation is when an inverse FFT is applied to the obtained CSI associated with the one or more radio channels. Another example of a transformation is when a radio channel is transformed into beam space by applying an FFT based transformation to the obtained CSI associated with the one or more radio channels.

When the classifier for classifying CSI compression quality is implemented by a UE, the input data to the classifier may refer to a subset of antenna ports associated with the radio channel H. In multi-antenna transmissions originated from same site, channels across antenna ports can be highly correlated and therefore channel data from a subset of the antenna ports may be used to predict a class in the classification of CSI compression quality. This is exemplified by a channel slicing operation as shown in FIG. 7(c).

In another embodiment, where the UE implements the classifier for classifying the CSI compression quality, the classifier obtains one or more slices (h) from the radio channel H as input.

In another embodiment, where the UE implements a classifier for classifying the CSI compression quality, the classifier obtains slices of a transformed radio channel as input. One example of such transformation is when the slices refer to one or more set of channel impulse response, CIR, samples, obtained by applying an inverse FFT to a radio channel H.

A related example is when the slices refer to amplitude CIRs obtained by taking the absolute value of complex-valued CIR samples. Another example is when the channel slices refer to radio channels that have been transformed from antenna space to beam space.

FIG. 8(a) is another implementation example of a classifier, according to some embodiments, in which a neural network-based classifier uses transfer learning from an AE-encoder. The AE-encoder is re-used by the classifier as an untrainable part of the neural network-based classifier in which only the “Dense” part is trainable. With the use of transfer learning, only the added dense layers are trained in a supervised learning manner. The pre-trained encoder, part of the classifier, can be viewed as a transformation step of the channel slices into a latent code, Z.

In an embodiment, where the UE implements a neural network-based classifier for classifying the CSI compression quality, transfer learning of AE-encoder layers is used in the construction of the classifier. In training of the classifier, the transfer learned layers are frozen and are not updated through any backpropagation.

One example of labelling for binary classification is shown in FIG. 8(b), where the norm of the performance loss, ∥\tilde{H}∥, is compared to a threshold value α. This threshold value may correspond to a percentile value from a cumulative distribution function, CDF, derived by determining the norm of the performance loss. In this binary labeling example, supervised learning of a classifier may then be performed by using the outcome of the labeling, where in this binary example a label, or class, “1” represents the case where the norm of the performance loss is above the threshold value α, otherwise “0” is assigned as label or class. The percentile value and the corresponding threshold value α may be selected to reflect the border of acceptable versus unacceptable performance loss when using a reconstructed channel.

Any of the exemplified classifier implementations shown in FIG. 7 and FIG. 8(a) may be used to perform either binary or multi-class classification, with input data to a classifier according to some embodiments.

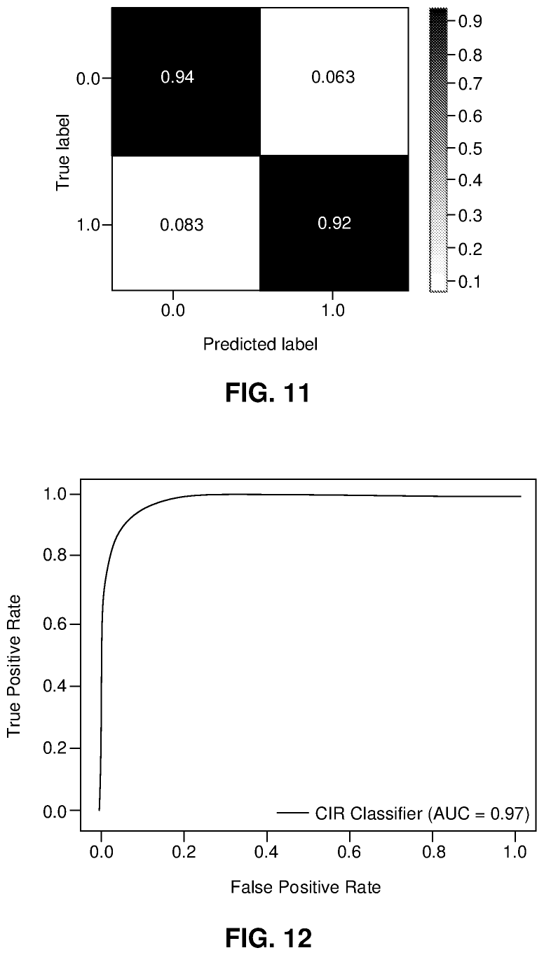

FIGS. 11 and 12 exemplifies prediction accuracy measures of a neural network based binary classifier used for classifying CSI compression quality, where FIG. 11 shows a confusion matrix and FIG. 12 shows a receiver operating characteristic, ROC, plot. These FIGS. 11 and 12 have been obtained for the classifier structure shown in FIG. 8, where one antenna port has been sliced out from a MIMO radio channel as input to the classifier. Further, the transfer learning shown in FIG. 8(a) corresponds in this example to using the encoder part of a feedforward fully convolutional neural network, FCN, based autoencoder that has been trained to minimize the mean square error, MSE, of the performance loss \tilde{H}. Further, for the binary labelling shown in FIG. 8(b), the threshold a has been selected to correspond to a 90% percentile value of a CDF derived by determining the norm of performance loss. In this example, the binary classifier included one fully connected (dense) layer, representing the only trainable part of the transfer learning based classifier shown in FIG. 8(a).

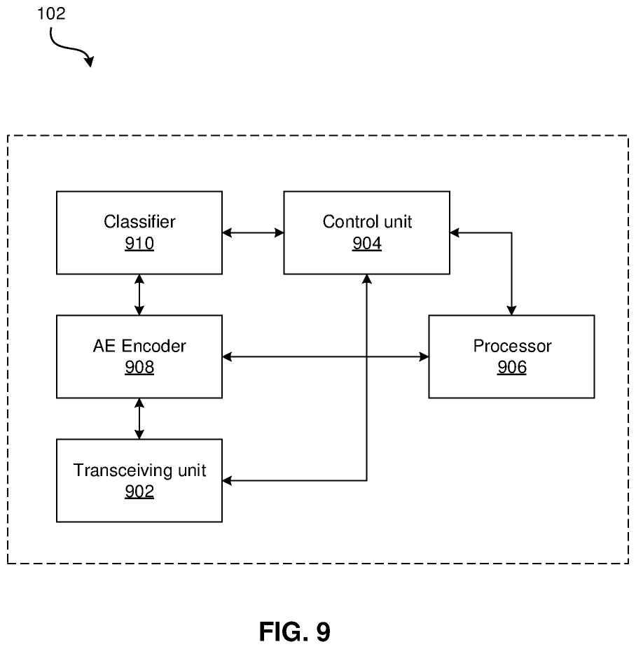

FIG. 9 is an example schematic diagram showing functional modules of the UE according to some embodiments. As depicted in FIG. 9, the UE 102 may comprise means arranged to perform the method for classifying the CSI compression quality.

According to at least some embodiments of the present invention, the UE 102 in FIG. 9 comprises a transceiving unit 902, a processor 906, an AE Encoder 908 and a classifier 910. In addition, the UE 102 may also comprise a control unit 904, adapted to control said units.

It can be mentioned that the AE encoder 908 and the classifier 910 may be merged into the processor 604, which may be called a data processing unit, potentially also covering the control unit 904.

The AE encoder 908, the classifier 910 and the transceiving unit 902 as well as the control unit 904, may be operatively connected to each other.

The function of the classifier 910, when encompassed by the processing unit, may be performed by classifying means of the processing unit.

The classifier 910 may be adapted to classify the CSI compression quality related to reconstruction of the one or more radio channels of the compressed CSI using a classifier predicting performance loss associated with the reconstruction of the one or more radio channels used in the compression.

The AE Encoder 908 may be adapted to compress the CSI associated with the one or more radio channels into an encoded format representing a compressed CSI. Further, the AE Encoder 908 may be adapted to provide the encoded format representing a compressed CSI to the classifier for classifying the CSI compression quality.

The transceiving unit 902 may be adapted to transmit one or more of: the CSI compression quality classification and the encoded format representing the compressed CSI to the base station in the wireless communication network.

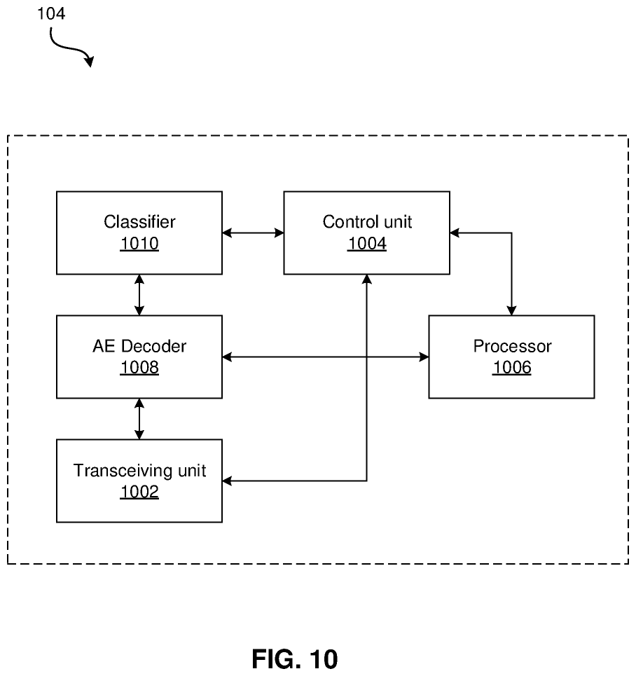

FIG. 10 is an example schematic diagram showing functional modules of the network node according to some embodiments. The network node in the form of a base station of a wireless communication network is capable of classifying the CSI compression quality.

As depicted in FIG. 10, the base station 104 may comprise means arranged to perform the method for classifying the CSI compression quality.

According to at least some embodiments of the present invention, the base station 104 in FIG. 10 comprises a transceiving unit 1002, a processor 1006, an AE Decoder 1008 and a classifier 1010. In addition, the base station 104 may also comprise a control unit 904, adapted to control said units.

It can be mentioned that the AE Decoder 1008 and the classifier 910 may be merged into the processor 1004, which may be called a data processing unit, potentially also covering the control unit 1004.

The AE Decoder 1008, the classifier 1010 and the transceiving unit 1002 as well as the control unit 1004, may be operatively connected to each other.

The function of the classifier 1010, when encompassed by the processing unit, may be performed by classifying means of the processing unit.

The classifier 1010 may be adapted to classify the CSI compression quality related to reconstruction of the one or more radio channels of the compressed CSI using a classifier predicting performance loss associated with the reconstruction of the one or more radio channels used in the compression.

The AE Decoder 1008 may be adapted to compress the CSI associated with the one or more radio channels into an encoded format representing a compressed CSI. Further, the AE Decoder 1008 may be adapted to provide the encoded format representing a compressed CSI to the classifier for classifying the CSI compression quality.

The transceiving unit 1002 may be adapted to transmit one or more of: the CSI compression quality classification and the encoded format representing the compressed CSI to the base station in the wireless communication network.

FIG. 11 is a graph showing predicted classification of CSI compression quality according to some embodiments. From the graph, it may be evident that the exemplified classifier is highly capable of predicting the binary classes correctly, in which the classes “0” and 1” is predicted correctly with rates of 94% and 92%, respectively.

FIG. 12 is a graph showing receiver operating characteristic, ROC, of CSI compression quality according to some embodiments. From the ROC curve in FIG. 12, area under curve, AUC may be determined, which refers to the ratio of the area that is underneath the ROC curve. The AUC value is identified to be 0.97 for the exemplified neural network based classifier for classifying the CSI compression quality, which indicates a good classification of the CSI compression quality.

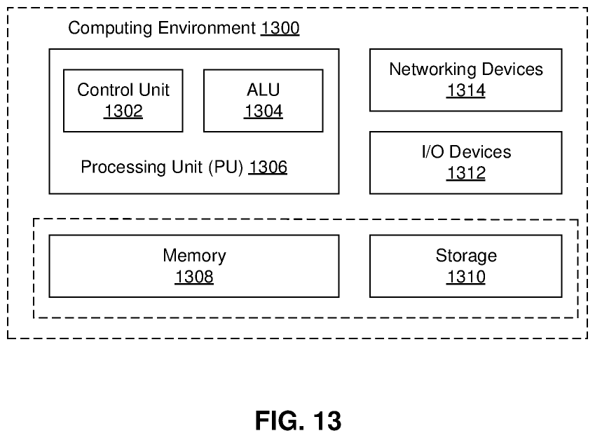

FIG. 13 illustrates an example computing environment 1300 implementing a method and the network node and the UE for classifying the CSI compression quality as described in FIG. 3 and FIG. 4. As depicted in FIG. 13, the computing environment 1300 comprises at least one data processing unit 1306 that is equipped with a control unit 1302 and an Arithmetic Logic Unit, ALU 1304, a memory 1308, a storage 1310, plurality of networking devices 1314 and a plurality Input output, I/O devices 1312. The data processing unit 1306 is responsible for processing the instructions of the algorithm. For example, the data processing unit 1306 is equivalent to the processor of the network node. The data processing unit 1306 is capable of executing software instructions stored in memory 1308. The data processing unit 1306 receives commands from the control unit 1302 in order to perform its processing. Further, any logical and arithmetic operations involved in the execution of the instructions are computed with the help of the ALU 1304.

The computer program is loadable into the data processing unit 1306, which may, for example, be comprised in an electronic apparatus (such as a UE or a network node). When loaded into the data processing unit 1306, the computer program may be stored in the memory 1308 associated with or comprised in the data processor. According to some embodiments, the computer program may, when loaded into and run by the data processing unit 1306, cause execution of method steps according to, for example, any of the methods illustrated in FIGS. 3 and 4 or otherwise described herein

The overall computing environment 1300 may be composed of multiple homogeneous and/or heterogeneous cores, multiple CPUs of different kinds, special media and other accelerators. The data processing unit 1306 is responsible for processing the instructions of the algorithm. Further, the plurality of data processing units 1306 may be located on a single chip or over multiple chips.

The algorithm comprising of instructions and codes required for the implementation are stored in either the memory 1308 or the storage 1310 or both. At the time of execution, the instructions may be fetched from the corresponding memory 1308 and/or storage 1310, and executed by the data processing unit 1306.

In case of any hardware implementations various networking devices 1314 or external I/O devices 1312 may be connected to the computing environment to support the implementation through the networking devices 1314 and the I/O devices 1312.

The embodiments disclosed herein can be implemented through at least one software program running on at least one hardware device and performing network management functions to control the elements. The elements shown in FIG. 13 include blocks which can be at least one of a hardware device, or a combination of hardware device and software module.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the scope of the disclosure.

1. A method for classifying channel state information (CSI) compression quality, the method being performed by a user equipment (UE) in a wireless communication network, wherein the method comprises:
obtaining CSI associated with one or more radio channels;
compressing the CSI into an encoded format representing a compressed CSI; and
classifying a CSI compression quality related to reconstruction of the one or more radio channels of the compressed CSI using a classifier predicting a resulting performance loss associated with the reconstruction of the one or more radio channels, wherein the classification of the CSI compression quality is based on a level of predicted performance loss.

2. The method according to claim 1, further comprising:
transmitting one or more of the CSI compression quality classification and the encoded format representing the compressed CSI to a network node in the wireless communication network.

3. The method according to claim 2, wherein the transmitting comprises:
determining whether the CSI compression quality classification triggers a secondary CSI report; and
transmitting one or more of the CSI compression quality classification and the secondary CSI report when it is determined that CSI compression quality classification triggers a secondary CSI report.

4. The method according to claim 3, wherein the secondary CSI report is configured by the network node.

5. The method according to claim 3, wherein a type of the secondary CSI report is configured by the network node.

6. The method according to claim 3, wherein the secondary CSI report is an NR CSI type I report.

7. The method according to claim 1, wherein the CSI compression quality is classified using a neural network based classifier.

8. The method according to claim 7, wherein the neural network based classifier is configured by a network node.

9. The method according to claim 7, wherein the classifier is trained by:
generating an encoded format representing a compressed CSI for the one or more radio channels;
determining a performance loss associated with the reconstruction of a CSI from the compressed CSI;
defining two or more classification labels, wherein each of the classification label being associated with the level of determined performance loss; and
extracting input data to the classifier from data associated with the compression of the CSI; and
training the classifier using extracted input data and the two or more classification labels for classifying the CSI compression quality.

10. The method according to claim 9, wherein the CSI compression is performed by using a neural network, wherein the extracted input data to the classifier corresponds to one or more layers of a CSI compression based neural network.

11. The method according to claim 10, wherein the neural network is used to obtain a reconstructed CSI causing the performance loss from the encoded format representing the compressed CSI of the one or more radio channels.

12. The method according to claim 11, wherein the neural network represents a decoder of an autoencoder.

13. A method for classifying channel state information (CSI) compression quality, the method being performed by a network node in a wireless communication network, wherein the method comprises:
receiving an encoded format representing a compressed CSI from a user equipment UE; and
classifying a CSI compression quality related to reconstruction of one or more radio channels of the compressed CSI using a classifier predicting a resulting performance loss associated with the reconstruction of the one or more radio channels, wherein the classification of the CSI compression quality is based on a level of predicted performance loss.

14. The method according to claim 13, wherein the CSI compression quality is classified using a neural network based classifier.

15. The method according to claim 13, further comprising:
deciding on how to use a CSI feedback for scheduling the UE using the classified CSI compression quality.

16. The method according to claim 15, wherein the deciding comprises:
deciding whether to schedule a multi-user MIMO or a single-user MIMO transmission for the UE using the classified CSI compression quality.

17. The method according to claim 13, wherein the classifier is trained by:
generating an encoded format representing a compressed CSI for the one or more radio channels;
determining a performance loss associated with the reconstruction of a CSI from the compressed CSI;
defining two or more classification labels, wherein each of the classification label being associated with the level of determined performance loss;
extracting input data to the classifier from data associated with the reconstruction or decompression of the compressed CSI; and
training the classifier using the extracted input data and the two or more classification labels for classifying the CSI compression quality.

18. The method according to claim 17, wherein the reconstruction of CSI or decompression of CSI is performed by using a neural network, wherein the extracted input data to the classifier corresponds to one or more layers of the neural network used to reconstruct or decompress the compressed CSI of the one or more radio channels.

19. The method according to claim 18, wherein the neural network is used to obtain the reconstructed CSI from the encoded format representing the compressed CSI of the one or more radio channels.

20. The method according to claim 19, wherein the neural network represents a decoder of an autoencoder.

21-41. (canceled)
